(19) United States
(12) Patent Application Publication
(10) Pub. No.: US 2025/0226330 A1
(43) Pub. Date: Jul. 10, 2025

(54) SEMICONDUCTOR PACKAGE DEVICE AND SEMICONDUCTOR WIRING SUBSTRATE THEREOF

(71) Applicants: GLOBAL UNICHIP CORPORATION, HSINCHU CITY (TW); TAIWAN SEMICONDUCTOR MANUFACTURING COMPANY, LTD., Hsinchu (TW)

(72) Inventors: Wei-Chiao WANG, HSINCHU CITY (TW); Sheng-Fan YANG, HSINCHU CITY (TW); Chih-Chiang HUNG, HSINCHU CITY (TW); Yuan-Hung LIN, HSINCHU CITY (TW); Yi-Tzeng LIN, HSINCHU CITY (TW); Hao-Yu TUNG, HSINCHU CITY (TW)

(21) Appl. No.: 18/761,335

(22) Filed: Jul. 2, 2024

(30) Foreign Application Priority Data
Jan. 9, 2024 (TW) 113100937

(51) Int. Cl. H01L 23/538; H01L 23/00; H01L 23/58; H01L 25/065; H10B 80/00

(52) U.S. Cl. CPC H01L 23/5386; H01L 23/5383; H01L 23/585; H01L 24/16; H01L 25/0655; H01L 2224/16227; H10B 80/00

(57) ABSTRACT

A semiconductor wiring substrate includes at least one circuit layer, at least one dielectric layer and a redistribution layer. The at least one circuit layer includes multiple signal traces and multiple ground traces alternately arranged on the at least one circuit layer, and has a channel width in a direction. The at least one dielectric layer is between the at least one circuit layer. The redistribution layer is above the at least one circuit layer, allows a first solder bump and a second solder bump to be placed, and includes a first metal contact and a second metal contact. The first solder bump and the second solder bump connect the at least one circuit layer through the first metal contact and the second metal contact, respectively. The channel width is greater than spacing between the first solder bump and the second solder bump in the direction.

### CROSS-REFERENCE TO RELATED APPLICATION

This application claims priority to Taiwan Application Serial Number 113100937, filed on Jan. 9, 2024, which is herein incorporated by reference in its entirety.

### BACKGROUND

### Field of Invention

This disclosure relates to a semiconductor wiring substrate, and in particular to a semiconductor wiring substrate of a semiconductor package device.

### Description of Related Art

With the increasing applications of the high-bandwidth memory, the requirements for the routing flexibility and signal integrity also increase. Therefore, it is necessary to improve existing design to meet the requirements.

### SUMMARY

An aspect of present disclosure relates to a semiconductor wiring substrate. The semiconductor wiring substrate includes at least one circuit layer, at least one dielectric layer and a redistribution layer. The at least one circuit layer includes a plurality of signal traces and a plurality of ground traces, wherein the plurality of signal traces and the plurality of ground traces are alternately arranged on the at least one circuit layer, and the at least one circuit layer has a channel width in a first direction. The at least one dielectric layer is arranged between the at least one circuit layer. The redistribution layer is arranged above the at least one circuit layer, is configured to allow at least one first solder bump and at least one second solder bump to be placed, and includes at least one first metal contact and at least one second metal contact, wherein the at least one first solder bump and the at least one second solder bump are electrically connected to the at least one circuit layer through the at least one first metal contact and the at least one second metal contact, respectively, so that the channel width is greater than a first spacing between the at least one first solder bump and the at least one second solder bump in the first direction.

Another aspect of present disclosure relates to a semiconductor package device. The semiconductor package device includes a first chip, a second chip, a package substrate and an interposer. The second chip is configured to perform a transmission of at least one signal with the first chip through at least one channel. The interposer includes a semiconductor wiring substrate, a first surface and a second surface, wherein the first surface and the second surface are opposite to each other, the first chip and the second chip are electrically connected to the first surface, and the package substrate is electrically connected to the second surface. The semiconductor wiring substrate includes at least one circuit layer, at least one dielectric layer and a redistribution layer. The at least one circuit layer is electrically coupled between the first chip and the second chip as the at least one channel, and includes a plurality of signal traces and a plurality of ground traces, wherein the plurality of signal traces and the plurality of ground traces are alternately arranged on the at least one circuit layer, and the at least one circuit layer has a channel width in a first direction. The at least one dielectric layer is arranged between the at least one circuit layer. The redistribution layer is arranged above the at least one circuit layer, is configured to allow at least one first solder bump and at least one second solder bump to be placed, and includes at least one first metal contact and at least one second metal contact, wherein the at least one first solder bump and the at least one second solder bump are electrically connected to the at least one circuit layer through the at least one first metal contact and the at least one second metal contact, respectively, so that the channel width is greater than a first spacing between the at least one first solder bump and the at least one second solder bump in the first direction.

### BRIEF DESCRIPTION OF THE DRAWINGS

FIG. 1 is a partial cross-section diagram of a semiconductor wiring substrate in accordance with some embodiments of the present disclosure;

FIG. 2 is a partial top view diagram of the semiconductor wiring substrate in accordance with some embodiments of the present disclosure;

FIG. 3 is a schematic diagram of a semiconductor package device in accordance with some embodiments of the present disclosure;

FIG. 4 is signal eye diagrams of a semiconductor package device using known art and a semiconductor package device using a configuration of the present disclosure at a lower transmission speed; and

FIG. 5 is signal eye diagrams of a semiconductor package device using known art and a semiconductor package device using a configuration of the present disclosure at a higher transmission speed.

### DETAILED DESCRIPTION

The embodiments are described in detail below with reference to the appended drawings to better understand the aspects of the present disclosure. However, the provided embodiments are not intended to limit the scope of the disclosure, and the description of the structural operation is not intended to limit the order in which they are performed. Any device that has been recombined by components and produces an equivalent function is within the scope covered by the disclosure.

The terms used in the entire specification and the scope of the patent application, unless otherwise specified, generally have the ordinary meaning of each term used in the field, the content disclosed herein, and the particular content.

The terms “coupled” or “connected” as used herein may mean that two or more elements are directly in physical or electrical contact, or are indirectly in physical or electrical contact with each other. It can also mean that two or more elements interact with each other.

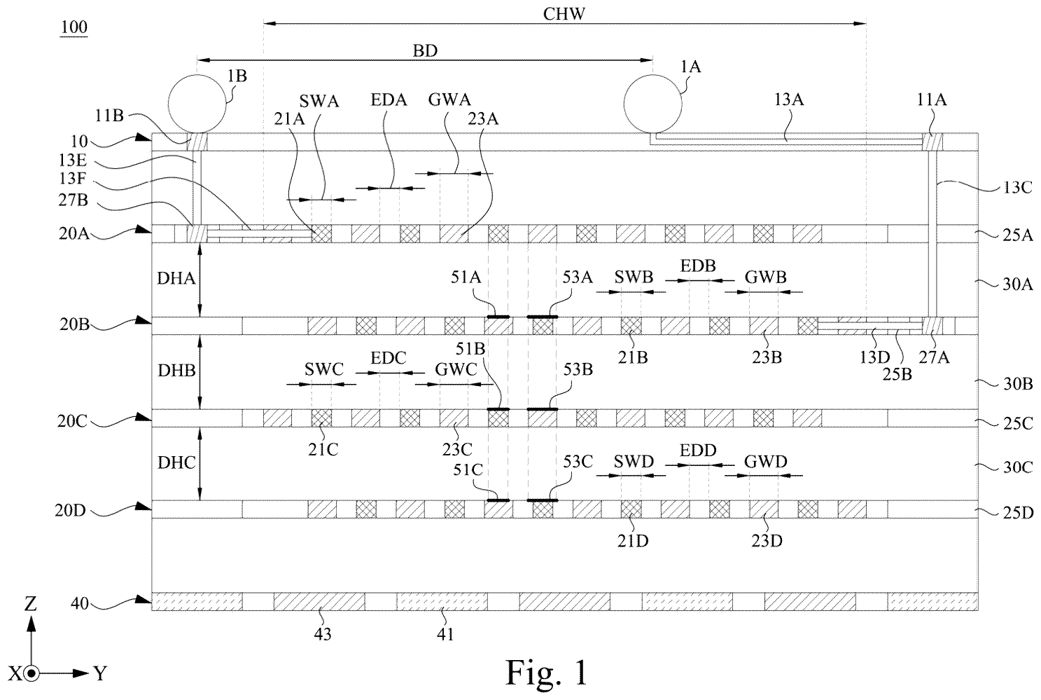

Referring to FIG. 1, FIG. 1 is a partial cross-section diagram of a semiconductor wiring substrate 100 in accordance with some embodiments of the present disclosure. In some embodiments, the semiconductor wiring substrate 100 includes a redistribution layer 10, at least one circuit layer, at least one dielectric layer and a power/ground layout layer 40.

For clarity and convenience of description, 4 circuit layers (i.e., a circuit layer 20A, a circuit layer 20B, a circuit layer 20C and a circuit layer 20D) and 3 dielectric layers (i.e., a dielectric layer 30A, a dielectric layer 30B and a dielectric layer 30C) are illustrated in FIG. 1. It should be understood that a number of the circuit layers in the semiconductor wiring substrate 100 is not limited to be 4, and a number of the dielectric layers in the semiconductor wiring substrate 100 is not limited to be 3.

In some embodiments, as shown in FIG. 1, the redistribution layer 10 is arranged above the circuit layer 20A as a top layer of the semiconductor wiring substrate 100. The redistribution layer 10 includes at least one first metal contact 11A and at least one second metal contact 11B. In particular, the first metal contact 11A and the second metal contact 11B are arranged on two opposite sides of the redistribution layer 10 in a direction Y.

In some embodiments, the circuit layer 20A includes a plurality of signal traces 21A, a plurality of ground traces 23A and at least one shielding structure 25A. In particular, the signal traces 21A and the ground traces 23A are alternately arranged on the circuit layer 20A in the direction Y. The shielding structures 25A are arranged on two opposite sides of the signal traces 21A and the ground traces 23A which are alternately arranged.

In some embodiments, the circuit layer 20B is arranged below the circuit layer 20A, and includes a plurality of signal traces 21B, a plurality of ground traces 23B and at least one shielding structure 25B. In particular, the signal traces 21B and the ground traces 23B are alternately arranged on the circuit layer 20B in the direction Y. The shielding structures 25B are arranged on two opposite sides of the signal traces 21B and the ground traces 23B which are alternately arranged.

In some embodiments, the circuit layer 20C is arranged below the circuit layer 20B, and includes a plurality of signal traces 21C, a plurality of ground traces 23C and at least one shielding structure 25C. In particular, the signal traces 21C and the ground traces 23C are alternately arranged on the circuit layer 20C in the direction Y. The shielding structures 25C are arranged on two opposite sides of the signal traces 21C and the ground traces 23C which are alternately arranged.

In some embodiments, the circuit layer 20D is arranged below the circuit layer 20C, and includes a plurality of signal traces 21D, a plurality of ground traces 23D and at least one shielding structure 25D. In particular, the signal traces 21D and the ground traces 23D are alternately arranged on the circuit layer 20D in the direction Y. The shielding structures 25D are arranged on two opposite sides of the signal traces 21D and the ground traces 23D which are alternately arranged.

In some embodiments, the dielectric layer 30A is arranged between the circuit layer 20A and the circuit layer 20B, the dielectric layer 30B is arranged between the circuit layer 20B and the circuit layer 20C, and the dielectric layer 30C is arranged between the circuit layer 20C and the circuit layer 20D. In other words, the at least one dielectric layer is arranged between the at least one circuit layer.

In some embodiments, the power/ground layout layer 40 is arranged below the circuit layer 20D, and includes a plurality of power layouts 41 and a plurality of ground layouts 43. In particular, the power layouts 41 and the ground layouts 43 are alternately arranged on the power/ground layout layer 40 in the direction Y.

It can be seen from the above descriptions that the redistribution layer 10, the circuit layer 20A, the dielectric layer 30A, the circuit layer 20B, the dielectric layer 30B, the circuit layer 20C, the dielectric layer 30C, the circuit layer 20D and the power/ground layout layer 40 are sequentially arranged in an opposite direction of a direction Z which is perpendicular to the direction Y.

It should be understood that the structure of the semiconductor wiring substrate 100 is not limited to be that as shown in FIG. 1. For example, in some embodiments, the power/ground layout layer 40 can be arranged at other positions, or can be omitted from the semiconductor wiring substrate 100.

The relative relationships among the circuit layers 20A-20D in FIG. 1 are further described then. As shown in FIG. 1, a projection 51A of one of the signal traces 21A of the circuit layer 20A on the circuit layer 20B in the opposite direction of the direction Z and one of the ground traces 23B are partially overlapped. Also, a projection 53A of one of the ground traces 23A of the circuit layer 20A on the circuit layer 20B in the opposite direction of the direction Z and one of the signal traces 21B are partially overlapped.

A projection 51B of one of the signal traces 21A of the circuit layer 20A on the circuit layer 20C in the opposite direction of the direction Z and one of the signal traces 21C are substantially fully overlapped. Also, a projection 53B of one of the ground traces 23A of the circuit layer 20A on the circuit layer 20C in the opposite direction of the direction Z and one of the ground traces 23C are substantially fully overlapped.

A projection 51C of one of the signal traces 21A of the circuit layer 20A on the circuit layer 20D in the opposite direction of the direction Z and one of the ground traces 23D are partially overlapped. Also, a projection 53C of one of the ground traces 23A of the circuit layer 20A on the circuit layer 20D in the opposite direction of the direction Z and one of the signal traces 21D are partially overlapped.

In other words, the signal trace 21A, the ground trace 23B, the signal trace 21C and the ground trace 23D are alternately arranged in the opposite direction of the direction Z, and the ground trace 23A, the signal trace 21B, the ground trace 23C and the signal trace 21D are alternately arranged in the opposite direction of the direction Z.

It can be seen from the above descriptions that the signal traces and the ground traces on the at least one circuit layer are all alternately arranged regardless of being in a horizontal or vertical direction (i.e., the direction Y or the direction Z).

In some embodiments, each signal trace 21A on the circuit 20A has a signal trace width SWA, and each ground trace 23A on the circuit 20A has a ground trace width GWA. Notably, the ground trace width GWA is greater than or equal to the signal trace width SWA. For example, the signal trace width SWA cab substantially be 2 μm, and the ground trace width GWA cab substantially be 2-4 μm. In such arrangements, the ground traces 23A can provide the shielding for the signal traces 21A, which further reduce the crosstalk among the signal traces 21A.

In accordance with the above descriptions, each signal trace 21B on the circuit 20B has a signal trace width SWB, and each ground trace 23B on the circuit 20B has a ground trace width GWB. Each signal trace 21C on the circuit 20C has a signal trace width SWC, and each ground trace 23C on the circuit 20C has a ground trace width GWC. Also, each signal trace 21D on the circuit 20D has a signal trace width SWD, and each ground trace 23D on the circuit 20D has a ground trace width GWD. The signal trace width SWB and the ground trace width GWB, the signal trace width SWC and the ground trace width GWC and the signal trace width SWD and the ground trace width GWD all have the same or similar arrangements as the signal trace width SWA and the ground trace width GWA, and therefore are not described herein.

In some embodiments, one of the signal traces 21A is spaced at an edge distance EDA from adjacent one of the ground traces 23A (i.e., one of the ground traces 23A which is directly adjacent to one of the signal traces 21A). One of the signal traces 21B is spaced at an edge distance EDB from adjacent one of the ground traces 23B. One of the signal traces 21C is spaced at an edge distance EDC from adjacent one of the ground traces 23C. Also, one of the signal traces 21D is spaced at an edge distance EDD from adjacent one of the ground traces 23D.

In some embodiments, the dielectric layer 30A has a thickness DHA in the direction Z, the dielectric layer 30B has a thickness DHB in the direction Z, and the dielectric layer 30C has a thickness DHC in the direction Z.

Notably, the thickness DHA can be greater than or equal to anyone of the signal trace width SWA, the signal trace width SWB, the signal trace width SWC and the signal trace width SWD, and can be greater than or equal to anyone of the edge distance EDA, the edge distance EDB, the edge distance EDC and the edge distance EDD. In such arrangements, the signal exchange between two circuit layers 20A and 20B which are directly adjacent in the semiconductor wiring substrate 100 can be effectively shielded. The thickness DHB and the thickness DHC have the same or similar arrangements as the thickness DHA, and therefore are not described herein.

In some further embodiments, the ground traces (e.g., the ground traces 23A and the ground traces 23B) on any two of the at least one circuit layer are not connected through conductive vias (e.g., through-silicon via) or similar structures. In other words, the dielectric layer 30A, the dielectric layer 30B and the dielectric layer 30C in FIG. 1 each can be partially devoid of the conductive vias or the similar structures.

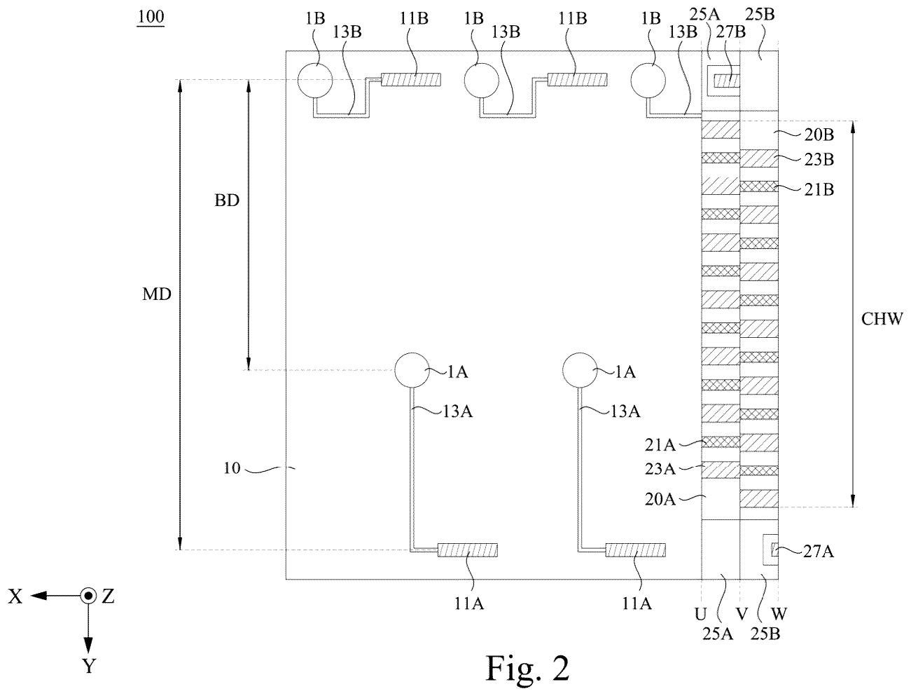

The semiconductor wiring substrate 100 is then further described with reference to FIG. 2. FIG. 2 is a partial top view diagram of the semiconductor wiring substrate 100 in accordance with some embodiments of the present disclosure.

In some embodiments, the redistribution layer 10 is configured to allow at least one first solder bump 1A and at least one second solder bump 1B to be placed. As shown in FIG. 2, the at least one first solder bump 1A is arranged on the redistribution layer 10 in a direction X perpendicular to the direction Y and the direction Z, and each first solder bump 1A is electrically connected to one preset first metal contact 11A through a conductive element 13A (e.g., a metal conducting wire). Similarly, the at least one second solder bump 1B is arranged on the redistribution layer 10 in the direction X, and each second solder bump 1B is electrically connected to one preset second metal contact 11B through a conductive element 13B (e.g., a metal conducting wire).

In some further embodiments, the at least one second solder bump 1B and the at least one second metal contact 11B are alternately arranged on the redistribution layer 10 in the direction X. In addition, the at least one first solder bump 1A and the at least one first metal contact 11A, which are spaced at a preset distance in the direction Y, are also alternately arranged on the redistribution layer 10 in the direction X. In such arrangements, a spacing BD between the at least one first solder bump 1A and the at least one second solder bump 1B in the direction Y is smaller than another spacing MD between the at least one first metal contact 11A and the at least one second metal contact 11B in the direction Y. It should be understood that the aforementioned preset distance can substantially be the spacing MD minus the spacing BD.

In FIG. 2, the top view of the circuit layer 20A is illustrated between two broken lines U and V, and the top view of the circuit layer 20B is illustrated between two broken lines V and W. In some embodiments, the circuit layer 20B further includes a third metal contact 27A, and the circuit layer 20A further includes a third metal contact 27B.

In some embodiments, as shown in FIG. 1, one preset first metal contact 11A on the redistribution layer 10 can be electrically connected to the third metal contact 27A on the circuit layer 20B through a conductive element 13C (e.g., a conductive via), and the third metal contact 27A can be further electrically connected to anyone of the signal traces 21B on the circuit layer 20B through a conductive element 13D (e.g., a metal conducting wire).

Similarly, one preset second metal contact 11B on the redistribution layer 10 can be electrically connected to the third metal contact 27B on the circuit layer 20A through a conductive element 13E (e.g., a conductive via), and the third metal contact 27B can be further electrically connected to anyone of the signal traces 21A on the circuit layer 20A through a conductive element 13F (e.g., a metal conducting wire).

It should be understood that the conductive element 13D and the conductive element 13F in FIG. 1 are only for illustrative purpose. Actually, the conductive element 13D is not electrically connected to the ground trace 23B and the shielding structure 25B, and the conductive element 13F is not electrically connected to the ground trace 23A and the shielding structure 25A.

As shown in FIG. 2 again, in order to not block the electrical connection of the third metal contact 27B with one corresponding signal trace 21A on the circuit layer 20A, the shielding structure 25A is at least partially surrounds the third metal contact 27B, and the shielding structure 25B is at least partially surrounds the third metal contact 27A. In such arrangements, the shielding structures (i.e., the shielding structure 25A and the shielding structure 25B) in the at least one circuit layer can provide the shielding for signals transmitted through the at least one first solder bump 1A and the at least one second solder bump 1B.

In the above embodiments, the shielding structures 25A-25D each can be implemented with the power layout or the ground layout. In particular, the power layout can be manufactured with the same materials as those forming the power layout 41, and the ground layout can be manufactured with the same materials as those forming the ground layout 43.

It should be understood that the at least one circuit layer in the semiconductor wiring substrate 100 is not limited to the structure as shown in FIG. 1 or 2. For example, in some embodiments, the shielding structures in the at least one circuit layer can be omitted in no consideration of providing the shielding for the signals transmitted through the at least one first solder bump 1A and the at least one second solder bump 1B.

It can be seen from the above descriptions that the at least one first solder bump 1A and the at least one second solder bump 1B are electrically connected to the at least one circuit layer through the at least one first metal contact 11A and the at least one second metal contact 11B, respectively. Notably, by such arrangements, a channel width CHW of the at least one circuit layer in the direction Y is greater than the spacing BD between the at least one first solder bump 1A and the at least one second solder bump 1B in the direction Y, which also shows that the semiconductor wiring substrate 100 has the advantages of increased routing flexibility.

In particular, as shown in FIGS. 1 and 2, the channel width CHW is a distance from an outer edge of one (e.g., the leftmost ground trace 23A on the circuit layer 20A in FIG. 1) of the signal traces 21A and the ground traces 23A, which is the closest to the shielding structure 25A, to an outer edge of one (e.g., the rightmost ground trace 23B on the circuit layer 20B in FIG. 1) of the signal traces 21B and the ground traces 23B, which is the closest to the shielding structure 25B.

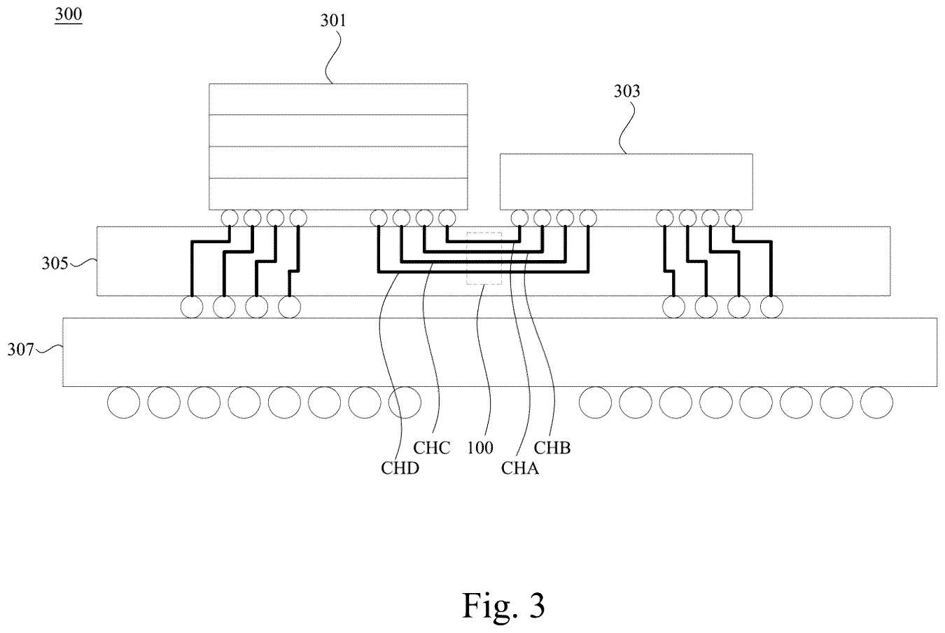

Referring to FIG. 3, FIG. 3 is a schematic diagram of a semiconductor package device 300 in accordance with some embodiments of the present disclosure. In some embodiments, the semiconductor package device 300 includes a memory chip 301 (i.e., a first chip), a processing chip 303 (i.e., a second chip), an interposer 305 and a package substrate 307.

As shown in FIG. 3, the memory chip 301 and the processing chip 303 can be connected to a first surface of the interposer 305 by multiple conductive elements (e.g., bonding pads, solder balls, solder bumps, etc.), and the package substrate 307 can be connected to a second surface of the interposer 305 by multiple conductive elements (e.g., bonding pads, solder balls, solder bumps, etc.), in which the first surface (e.g., a top surface) of the interposer 505 and the second surface (e.g., a bottom surface) of the interposer 505 are opposite to each other.

In some embodiments, the processing chip 303 is electrically coupled to the memory chip 301 through the interposer 305, and is configured to perform a transmission of at least one signal (not shown) with the memory chip 301 through at least one channel. For clarity and convenience of description, in FIG. 3, 4 channels (i.e., a channel CHA, a channel CHB, a channel CHC and a channel CHD) are illustrated. It should be understood that a number of the channels is not limited to be 4.

In some embodiments, the interposer 305 includes the semiconductor wiring substrate 100 of the aforementioned embodiments. In particular, the circuit layer 20A of the semiconductor wiring substrate 100 can be electrically coupled between the processing chip 303 and the memory chip 301 as the channel CHA, so that the processing chip 303 and the memory chip 301 can transmit a first signal of the at least one signal through the signal traces 21A on the circuit layer 20A.

The circuit layer 20B of the semiconductor wiring substrate 100 can be electrically coupled between the processing chip 303 and the memory chip 301 as the channel CHB, so that the processing chip 303 and the memory chip 301 can transmit a second signal of the at least one signal through the signal traces 21B on the circuit layer 20B.

The circuit layer 20C of the semiconductor wiring substrate 100 can be electrically coupled between the processing chip 303 and the memory chip 301 as the channel CHC, so that the processing chip 303 and the memory chip 301 can transmit a third signal of the at least one signal through the signal traces 21C on the circuit layer 20C.

The circuit layer 20D of the semiconductor wiring substrate 100 can be electrically coupled between the processing chip 303 and the memory chip 301 as the channel CHD, so that the processing chip 303 and the memory chip 301 can transmit a fourth signal of the at least one signal through the signal traces 21D on the circuit layer 20D.

In some embodiments, the power/ground layout layer 40 of the semiconductor wiring substrate 100 can be electrically coupled between the processing chip 303 and the memory chip 301, and is configured to transmit the supply power.

In the embodiments of FIG. 3, the memory chip 301 can be implemented by a high-bandwidth memory, and the processing chip 303 can be implemented by a system on chip (SoC).

It should be understood that the first signal, the second signal, the third signal and the fourth signal can be all same or all different, or can be part same, part different. In addition, each signal can include multiple sub-signals (e.g., data signals, address signals, clock signals, control signals, etc.). Notably, because each signal is transmitted on the corresponding circuit layer, the impedance distribution of each circuit layer is uniform, and the delays or skews among the sub-signals are reduced, so that the signal quality is raised.

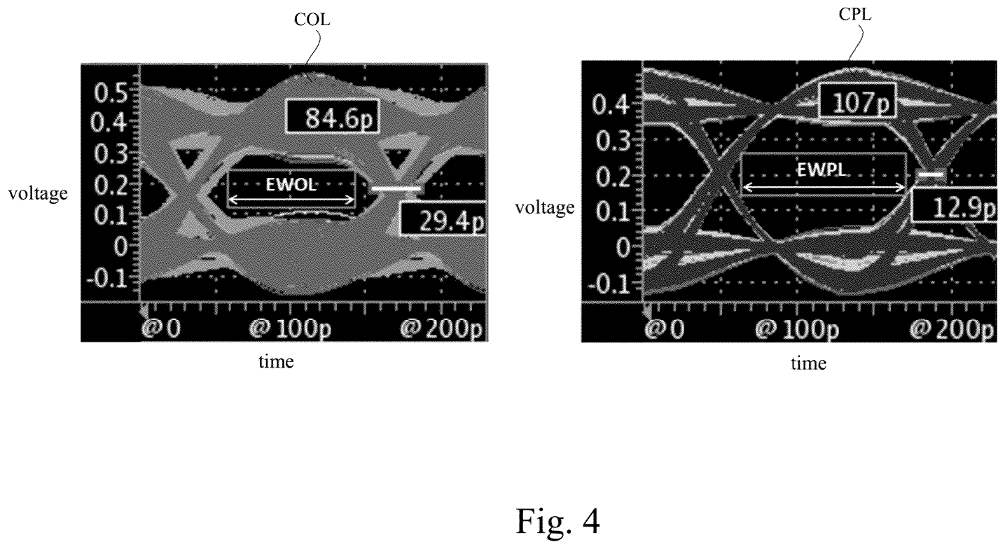

Referring to FIG. 4, FIG. 4 is signal eye diagrams of a semiconductor package device using known art and a semiconductor package device using a configuration of the present disclosure at a lower transmission speed (e.g., 7.2 Gbps). As shown in FIG. 4, a curve COL presents the signal eye diagram of the semiconductor package device using the known art at the lower transmission speed, and a curve CPL presents the signal eye diagram of the semiconductor package device using the configuration of the present disclosure at the lower transmission speed. It can be seen from FIG. 4 that the semiconductor package device (e.g., the semiconductor package device 300) using the configuration of the present disclosure has a better eye width at the lower transmission speed in comparison to the known art. For example, an eye width EWPL of the curve CPL is increased by about 26.4% in comparison to an eye width EWOL of the curve COL.

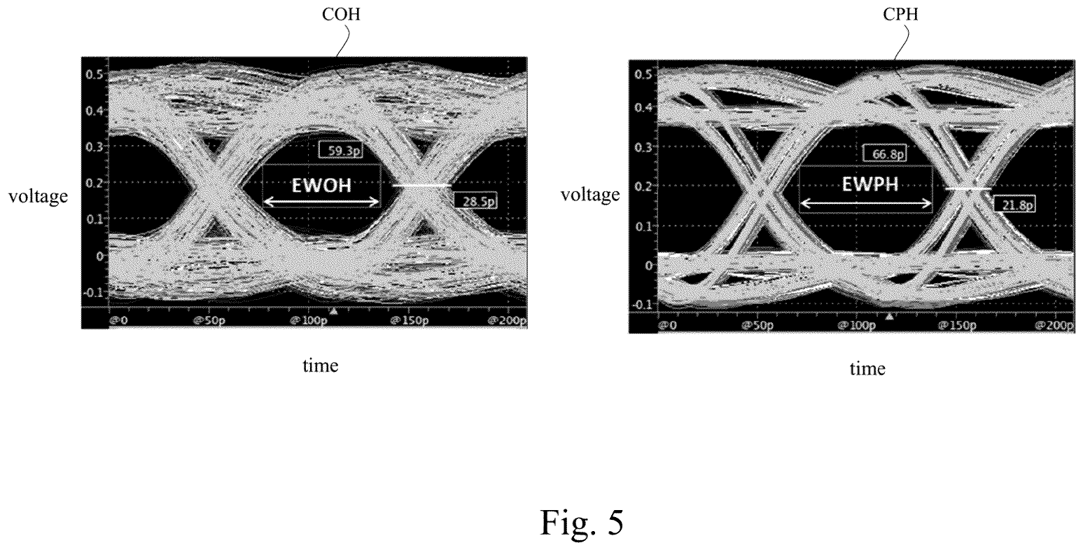

Referring to FIG. 5, FIG. 5 is signal eye diagrams of a semiconductor package device using known art and a semiconductor package device using a configuration of the present disclosure at a higher transmission speed (e.g., 9.6 Gbps). As shown in FIG. 5, a curve COH presents the signal eye diagram of the semiconductor package device using the known art at the higher transmission speed, and a curve CPH presents the signal eye diagram of the semiconductor package device using the configuration of the present disclosure at the higher transmission speed. It can be seen from FIG. 5 that the semiconductor package device (e.g., the semiconductor package device 300) using the configuration of the present disclosure has a better eye width at the lower transmission speed in comparison to the known art. For example, an eye width EWPH of the curve CPH is increased by about 12.7% in comparison to an eye width EWOH of the curve COH.

By using the redistribution layer 10 to achieve the electrical connection among the first solder bumps 1A, the second solder bumps 1B and at least one circuit layer, the semiconductor wiring substrate 100 of the present disclosure can alternately arrange the signal traces and the ground traces on the at least one circuit layer in a setting that the ground trace width is greater than the signal trace width without increasing the spacing BD between the first solder bumps 1A and the second solder bumps 1B. Also, the semiconductor wiring substrate 100 of the present disclosure has the wide channel width CHW.

In accordance with the above descriptions, even if the signal traces and the ground traces are alternately arranged on the at least one circuit layer in a setting that the ground trace width is equal to the signal trace width, by the redistribution layer 10, the semiconductor wiring substrate 100 of the present disclosure can increase a number of the signal traces included by each circuit layer without increasing the spacing BD between the first solder bumps 1A and the second solder bumps 1B.

As can be further seen from the above embodiments of the present disclosure, the semiconductor package device 300 and the semiconductor wiring substrate 100 of the present disclosure further have the advantages of increasing the routing flexibility, improving the signal integrity, reducing the cost, etc.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the invention. In view of the foregoing, it is intended that the present invention cover modifications and variations of this invention provided they fall within the scope of the following claims.

What is claimed is:

1. A semiconductor wiring substrate, comprising:
at least one circuit layer, comprising a plurality of signal traces and a plurality of ground traces, wherein the plurality of signal traces and the plurality of ground traces are alternately arranged on the at least one circuit layer, and the at least one circuit layer has a channel width in a first direction;
at least one dielectric layer, between the at least one circuit layer; and
a redistribution layer, arranged above the at least one circuit layer, configured to allow at least one first solder bump and at least one second solder bump to be placed, and comprising at least one first metal contact and at least one second metal contact, wherein the at least one first solder bump and the at least one second solder bump are electrically connected to the at least one circuit layer through the at least one first metal contact and the at least one second metal contact, respectively, so that the channel width is greater than a first spacing between the at least one first solder bump and the at least one second solder bump in the first direction.

2. The semiconductor wiring substrate of claim 1, wherein the plurality of signal traces each has a signal trace width, the plurality of ground traces each has a ground trace width, and the ground trace width is greater than or equal to the signal trace width.

3. The semiconductor wiring substrate of claim 1, wherein the at least one circuit layer further comprises at least one shielding structure and at least one third metal contact, the at least one first metal contact and the at least one second metal contact are connected to at least corresponding one of the plurality of signal traces through the at least one third metal contact, and the at least one shielding structure at least partially surrounds the at least one third metal contact.

4. The semiconductor wiring substrate of claim 3, wherein the at least one shielding structure is a power layout or a ground layout.

5. The semiconductor wiring substrate of claim 1, wherein the first spacing is smaller than a second spacing between the at least one first metal contact and the at least one second metal contact in the first direction.

6. The semiconductor wiring substrate of claim 1, wherein the at least one dielectric layer has a thickness in a second direction perpendicular to the first direction, the plurality of signal traces each has a signal trace width, one of the plurality of signal traces is spaced at an edge distance from adjacent one of the plurality of ground traces, and the thickness of the at least one dielectric layer is greater than or equal to the signal trace width and the edge distance.

7. The semiconductor wiring substrate of claim 1, wherein the at least one circuit layer comprises:
a first circuit layer, comprising a plurality of first signal traces, a plurality of first ground traces and a first shielding structure, wherein the plurality of first signal traces and the plurality of first ground traces are alternately arranged on the first circuit layer, and the first shielding structure is arranged on two opposite sides of the plurality of first signal traces and the plurality of first ground traces which are alternately arranged; and
a second circuit layer, arranged below the first circuit layer, and comprising a plurality of second signal traces, a plurality of second ground traces and a second shielding structure, wherein the plurality of second signal traces and the plurality of second ground traces are alternately arranged on the second circuit layer, and the second shielding structure is arranged on two opposite sides of the plurality of second signal traces and the plurality of second ground traces which are alternately arranged;
wherein a distance from an outer edge of one of both the plurality of first signal traces and the plurality of first ground traces, which is the closest to the first shielding structure, to an outer edge of one of both the plurality of second signal traces and the plurality of second ground traces, which is the closest to the second shielding structure, is the channel width.

8. The semiconductor wiring substrate of claim 7, wherein the at least one circuit layer further comprises:
a third circuit layer, arranged below the second circuit layer, and comprising a plurality of third signal traces, a plurality of third ground traces and a third shielding structure, wherein the plurality of third signal traces and the plurality of third ground traces are alternately arranged on the third circuit layer, and the third shielding structure is arranged on two opposite sides of the plurality of third signal traces and the plurality of third ground traces which are alternately arranged;
wherein the at least one dielectric layer comprises:
a first dielectric layer, arranged between the first circuit layer and the second circuit layer; and
a second dielectric layer, arranged between the second circuit layer and the third circuit layer;
wherein a first projection of one of the plurality of first signal traces on the third circuit layer along a second direction perpendicular to the first direction and one of the plurality of third signal traces are fully overlapped, and a second projection of one of the plurality of first ground traces on the third circuit layer along the second direction and one of the plurality of third ground traces are fully overlapped.

9. The semiconductor wiring substrate of claim 7, wherein a first projection of one of the plurality of first signal traces on the second circuit layer along a second direction perpendicular to the first direction and one of the plurality of second ground traces are partially overlapped, and a second projection of one of the plurality of first ground traces on the second circuit layer along the second direction and one of the plurality of second signal traces are partially overlapped.

10. The semiconductor wiring substrate of claim 1, further comprising:
a power/ground layout layer, arranged below the at least one circuit layer, and comprising a plurality of power layouts and a plurality of ground layouts.

11. A semiconductor package device, comprising:
a first chip;
a second chip, configured to perform a transmission of at least one signal with the first chip through at least one channel;
a package substrate; and
an interposer, comprising a semiconductor wiring substrate, a first surface and a second surface, wherein the first surface and the second surface are opposite to each other, the first chip and the second chip are electrically connected to the first surface, and the package substrate is electrically connected to the second surface;
wherein the semiconductor wiring substrate comprises:
at least one circuit layer, electrically coupled between the first chip and the second chip as the at least one channel, and comprising a plurality of signal traces and a plurality of ground traces, wherein the plurality of signal traces and the plurality of ground traces are alternately arranged on the at least one circuit layer, and the at least one circuit layer has a channel width in a first direction;
at least one dielectric layer, between the at least one circuit layer; and
a redistribution layer, arranged above the at least one circuit layer, configured to allow at least one first solder bump and at least one second solder bump to be placed, and comprising at least one first metal contact and at least one second metal contact, wherein the at least one first solder bump and the at least one second solder bump are electrically connected to the at least one circuit layer through the at least one first metal contact and the at least one second metal contact, respectively, so that the channel width is greater than a first spacing between the at least one first solder bump and the at least one second solder bump in the first direction.

12. The semiconductor package device of claim 11, wherein the plurality of signal traces each has a signal trace width, the plurality of ground traces each has a ground trace width, and the ground trace width is greater than or equal to the signal trace width.

13. The semiconductor package device of claim 11, wherein the at least one circuit layer further comprises at least one shielding structure and at least one third metal contact, the at least one first metal contact and the at least one second metal contact are connected to at least corresponding one of the plurality of signal traces through the at least one third metal contact, and the at least one shielding structure at least partially surrounds the at least one third metal contact.

14. The semiconductor package device of claim 13, wherein the at least one shielding structure is a power layout or a ground layout.

15. The semiconductor package device of claim 11, wherein the first spacing is smaller than a second spacing between the at least one first metal contact and the at least one second metal contact in the first direction.

16. The semiconductor package device of claim 11, wherein the at least one dielectric layer has a thickness in a second direction perpendicular to the first direction, the plurality of signal traces each has a signal trace width, one of the plurality of signal traces is spaced at an edge distance from adjacent one of the plurality of ground traces, and the thickness of the at least one dielectric layer is greater than or equal to the signal trace width and the edge distance.

17. The semiconductor package device of claim 11, wherein the at least one circuit layer comprises:
a first circuit layer, comprising a plurality of first signal traces, a plurality of first ground traces and a first shielding structure, wherein the plurality of first signal traces and the plurality of first ground traces are alternately arranged on the first circuit layer, and the first shielding structure is arranged on two opposite sides of the plurality of first signal traces and the plurality of first ground traces which are alternately arranged; and
a second circuit layer, arranged below the first circuit layer, and comprising a plurality of second signal traces, a plurality of second ground traces and a second shielding structure, wherein the plurality of second signal traces and the plurality of second ground traces are alternately arranged on the second circuit layer, and the second shielding structure is arranged on two opposite sides of the plurality of second signal traces and the plurality of second ground traces which are alternately arranged;
wherein a distance from an outer edge of one of both the plurality of first signal traces and the plurality of first ground traces, which is the closest to the first shielding structure, to an outer edge of one of both the plurality of second signal traces and the plurality of second ground traces, which is the closest to the second shielding structure, is the channel width.

18. The semiconductor package device of claim 17, wherein the at least one circuit layer further comprises:
a third circuit layer, arranged below the second circuit layer, and comprising a plurality of third signal traces, a plurality of third ground traces and a third shielding structure, wherein the plurality of third signal traces and the plurality of third ground traces are alternately arranged on the third circuit layer, and the third shielding structure is arranged on two opposite sides of the plurality of third signal traces and the plurality of third ground traces which are alternately arranged;
wherein the at least one dielectric layer comprises:
a first dielectric layer, arranged between the first circuit layer and the second circuit layer; and
a second dielectric layer, arranged between the second circuit layer and the third circuit layer;
wherein a first projection of one of the plurality of first signal traces on the third circuit layer along a second direction perpendicular to the first direction and one of the plurality of third signal traces are fully overlapped, and a second projection of one of the plurality of first ground traces on the third circuit layer along the second direction and one of the plurality of third ground traces are fully overlapped.

19. The semiconductor package device of claim 17, wherein a first projection of one of the plurality of first signal traces on the second circuit layer along a second direction perpendicular to the first direction and one of the plurality of second ground traces are partially overlapped, and a second projection of one of the plurality of first ground traces on the second circuit layer along the second direction and one of the plurality of second signal traces are partially overlapped.

20. The semiconductor package device of claim 11, wherein the semiconductor wiring substrate further comprises:
a power/ground layout layer, arranged below the at least one circuit layer, and comprising a plurality of power layouts and a plurality of ground layouts.
